(19) United States
(12) Patent Application Publication
(10) Pub. No.: US 2026/0231332 A1
(43) Pub. Date: Aug. 6, 2026

(54) 128 BYTE CACHE LINE MEMORY CONTROLLER FOR NON-STANDARD DIMM ARCHITECTURE

(71) Applicant: TACHYUM LTD., Las Vegas, NV (US)

(72) Inventors: Radoslav DANILAK, Henderson, NV (US); Pinchas HERMAN, Sunnyvale, CA (US); William RADKE, Santa Cruz, CA (US)

(73) Assignee: TACHYUM LTD., Las Vegas, NV (US)

(21) Appl. No.: 19/046,076

(22) Filed: Feb. 5, 2025

(51) Int. Cl. H05K 1/18

(52) U.S. Cl. CPC H05K 1/18; H05K 2201/10159; H05K 2201/10325

(57) ABSTRACT

A dual in-line memory module (DIMM) system is provided, and includes: a printed circuit board; a 144 bit system controller mounted on the printed circuit board; first and second 80 bit sockets mounted on the printed circuit board and connected to the 144 bit system controller; a first DIMM connected to the first 80 bit socket; a second DIMM connected to the second 80 bit socket; and a total processing capacity of the first and second DIMMs combined being 144 bits. The 144 bit system controller communicates with the first and second 80 bit sockets and the first and second DIMMs by a 128 byte cache line.

### FIELD OF THE INVENTION

Various embodiments described herein generally relate to a memory control for a non-standard DIMM architecture. More specifically, various embodiments relate to a 144 bit DIMM architecture.

### BACKGROUND

Dynamic random-access memory (DRAM) is a type of semiconductor memory that is typically used for the data or program code needed by a computer processor to function. DRAM is a common type of random-access memory (RAM) that is used in personal computers (PCs), laptops, workstations, and servers. DRAMs are typically provided as integrated circuit chips. DRAM chips currently support data widths of 4(×4 ), or 8 (×8 ), or 16 (×16 ) bits. Synchronous dynamic random-access memory (SDRAM) is a DRAM where an externally supplied clock signal coordinates the operation of its external pin interface.

A dual in-line memory module (DIMM) is a memory stick with a collection of several SDRAMs populating a printed circuit board. The stick is plugged into a socket of a computing device (e.g., server, personal computer, laptop, tablet, special purpose device, etc.)

Certain DIMM layouts have been set as standards to permit industry sources to universally manufacture compliant components. DDR5 DIMMs have significant advantages over DDM4 DIMMs, and are expected to become the dominant DIMM option for the next several years.

There has recently been an interest in utilizing a 144 bit DDR5 DIMM. However, there is no specific architecture available to support the same.

Referring now to FIG. 1, a prior art configuration 100 for an 80 bit DIMM is shown. A printed circuit board 102 supports an 80 bit controller 104, an 80 bit socket 106, and an 80 bit DIMM 108 with 80 bits of DRAM chips 110, all of which communicate via a 64 byte data cache line. This configuration, made from common off the shelf-components, at 80 bits is too small to support a 144 bit DIMM.

Referring now to FIG. 2, a prior art configuration 200 for a 160 bit DIMM is shown. The components are essentially two sets of the components from FIG. 1 mounted on the same printed circuit board. A printed circuit board 202 supports a first set of components including an 80 bit controller 204, an 80 bit socket 206, and an 80 bit DIMM 208 with 80 bits of DRAM chips 210, all of which communicate via a first 64 byte data cache line. Printed circuit board 202 also supports a second set of components including an 80 bit controller 212, an 80 bit socket 214, and an 80 bit DIMM 216 with 80 bits of DRAM chips 218, all of which communicate via a second 64 byte data cache line distinct from the first 64 byte cache line.

The above configuration of FIG. 2 has a variety of drawbacks for use as a 144 DIMM. Specifically, it uses too much space, requires too many pins, consumes too much power, and is expensive to manufacture.

### SUMMARY

According to an embodiment of the invention, a dual in-line memory module (DIMM) system is provided, and includes: a printed circuit board; a 144 bit system controller mounted on the printed circuit board; first and second 80 bit sockets mounted on the printed circuit board and connected to the 144 bit system controller; a first DIMM connected to the first 80 bit socket; a second DIMM connected to the second 80 bit socket; and a total processing capacity of the first and second DIMMs combined being 144 bits. The 144 bit system controller communicates with the first and second 80 bit sockets and the first and second DIMMs by a 128 byte cache line.

The above embodiment may have various optional features. The first DIMM may be an 80 bit DIMM populated with 80 bits of DRAM chips. The second DIMM may be a 64 bit DIMM, and may be an 80 bit sized DIMM populated with 64 bits of DRAM chips where 16 bits of DRAM chip space are unpopulated. The first 80 bit socket may be mounted on a top side of the printed circuit board, and the second 80 bit socket may be mounted on a bottom side of the printed circuit board. The system controller may have 36 clocking pins and/or 144 data pins. The first and second DIMMs may be 72 bit DIMMs.

According to another embodiment, a dual in-line memory module (DIMM) system, is provided and includes: a printed circuit board; a 144 bit system controller mounted on the printed circuit board; first and second 80 bit sockets mounted on the printed circuit board and connected to the 144 bit system controller; a first DIMM connected to the first 80 bit socket, the first DIMM being an 80 bit DIMM populated with 80 bits of DRAM chips; a second DIMM connected to the second 80 bit socket, the second DIMM being an 80 bit sized DIMM populated with 64 bits of DRAM chips and has 16 bits of DRAM chip space unpopulated; and a total processing capacity of the first and second DIMMs combined being 144 bits. The 144 bit system controller communicates with the first and second 80 bit sockets and the first and second DIMMs by a 128 byte cache line.

The above embodiment may have various optional features. The first 80 bit socket may be mounted on a top side of the printed circuit board, and the second 80 bit socket may be mounted on a bottom side of the printed circuit board. The system controller may have 36 clocking pins and/or 144 data pins.

### DRAWINGS

Various embodiments in accordance with the present disclosure will be described with reference to the drawings, as follows.

FIG. 1 shows an 80 bit DIMM architecture.

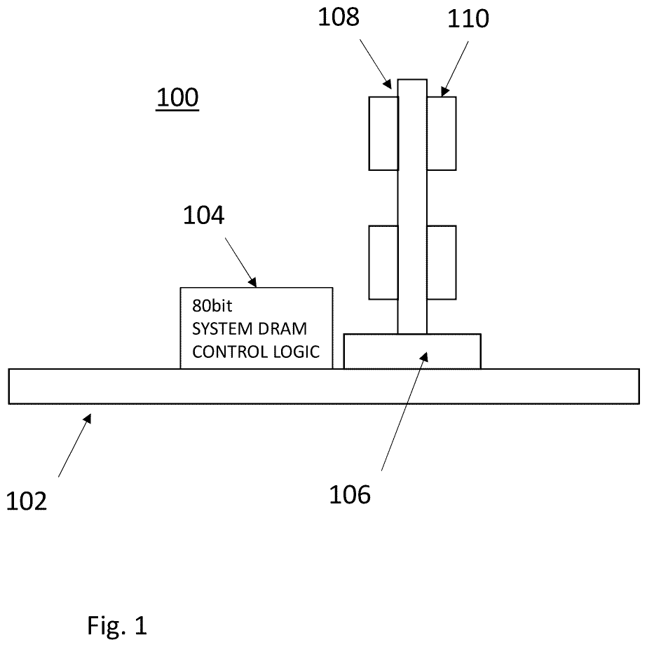

FIG. 2 shows an 160 bit DIMM architecture.

FIG. 3 shows a 144 bit DIMM architecture according to an embodiment of the invention.

FIG. 4 shows an 80 bit DIMM according to an embodiment of the invention.

FIG. 5 shows a 64 bit DIMM according to an embodiment of the invention.

FIG. 6 shows a 144 bit DIMM architecture according to another embodiment of the invention.

### DETAILED DESCRIPTION

In the following description, various embodiments will be illustrated by way of example and not by way of limitation in the figures of the accompanying drawings. References to various embodiments in this disclosure are not necessarily to the same embodiment, and such references mean at least one. While specific implementations and other details are discussed, it is to be understood that this is done for illustrative purposes only. A person skilled in the relevant art will recognize that other components and configurations may be used without departing from the scope and spirit of the claimed subject matter.

Specific details are provided in the following description to provide a thorough understanding of embodiments. However, it will be understood by one of ordinary skill in the art that embodiments may be practiced without these specific details. For example, systems may be shown in block diagrams so as not to obscure the embodiments in unnecessary detail. In other instances, well-known processes, structures and techniques may be shown without unnecessary detail in order to avoid obscuring example embodiments.

References to one or an embodiment in the present disclosure can be, but not necessarily are, references to the same embodiment; and, such references mean at least one of the embodiments.

References to any “example” herein (e.g., “for example”, “an example of”, by way of example” or the like) are to be considered non-limiting examples regardless of whether expressly stated or not.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various features are described which may be features for some embodiments but not other embodiments.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Several definitions that apply throughout this disclosure will now be presented.

The terms “substantial”, “substantially” or the like are defined to be essentially conforming to the particular dimension, shape, or other feature that the term modifies, such that the component need not be exact. For example, “substantially cylindrical” means that the object resembles a cylinder, but can have one or more deviations from a true cylinder. The terms are used as a modifier to imply “approximate” rather than “perfect.” It is a term of approximation, not a term of degree.

The term “comprising” when utilized means “including, but not necessarily limited to”; it specifically indicates open-ended inclusion or membership in the so-described combination, group, series and the like.

The term “a” means “one or more” unless the context clearly indicates a single element.

The term “about” when used in connection with a numerical value means a variation consistent with the range of error in equipment used to measure the values, for which ±5% may be expected.

“First,” “second,” etc., re labels to distinguish components or blocks of otherwise similar names, but does not imply any sequence or numerical limitation.

“And/or” for two possibilities means either or both of the stated possibilities (“A and/or B” covers A alone, B alone, or both A and B take together), and when present with three or more stated possibilities means any individual possibility alone, all possibilities taken together, or some combination of possibilities that is less than all of the possibilities. The language in the format “at least one of A . . . and N” where A through N are possibilities means “and/or” for the stated possibilities (e.g., at least one A, at least one N, at least one A and at least one N, etc.).

When an element is referred to as being “connected,” or “coupled,” to another element, it can be directly connected or coupled to the other element or intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

As used herein, the term “front”, “rear”, “left,” “right,” “top” and “bottom” or other terms of direction, orientation, and/or relative position are used for explanation and convenience to refer to certain features of this disclosure. However, these terms are not absolute, and should not be construed as limiting this disclosure.

Shapes as described herein are not considered absolute. As is known in the art, surfaces often have waves, protrusions, holes, recesses, etc. to provide rigidity, strength and functionality. All recitations of shape (e.g., cylindrical) herein are to be considered modified by “substantially” regardless of whether expressly stated in the disclosure or claims, and specifically accounts for variations in the art as noted above.

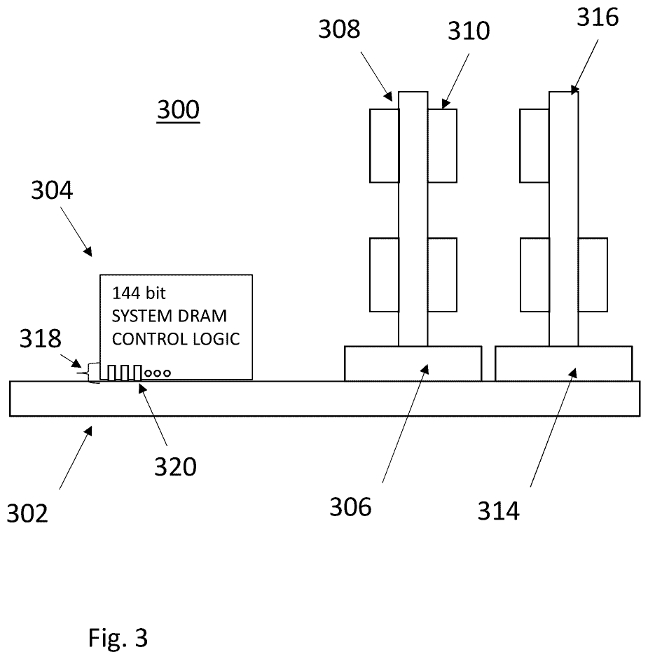

Referring now to FIG. 3, a 144 bit DIMM system architecture 300 is shown. A printed circuit board 302 supports an 144 bit controller 304, an 80 bit socket 306, and an 80 bit DIMM 308 with 80 bits of DRAM chips 310 connected to the 80 bit socket 306, an 80 bit socket 314, and a 64 bit DIMM 316 connected to the 80 bit socket 314, all of which communicate via a 128 byte data cache line. The 144 bit controller 304 has a pin set 318 of pins 320 for data and power interaction with the other components.

The 80 bit socket 306 and 80 bit socket 314 may be off the shelf components as is known in the art, and not further detailed herein.

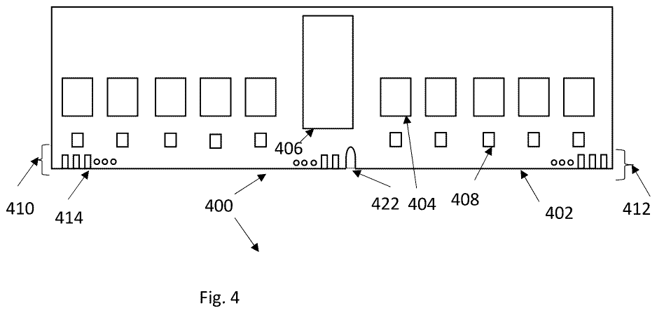

Referring now to FIG. 4, DDR5 80 bit DIMM 308 is shown in more detail. A printed circuit board 402 is shaped to support ten (10)×8 DRAM chips on one side thereof and includes ten (10)×8 DRAM chips 404, a central registered clock driver (RCD chip) 406, data buffers 408, and left and right pin sets 410 and 412 of individual pins 414 extending along the bottom of printed circuit board 402. A key slot 522 is sized and positioned to mate with a projection of 80 bit socket 306 of the supporting architecture (e.g., server, computer) to connect to the supporting architecture. Other components per the DDR5 standard as are known in the art (e.g., PMIC, SPD hub, temperature sensor, wiring, connectors, etc.) are not shown. The 80 bit DIMM 308 may thus be a standard off the shelf component.

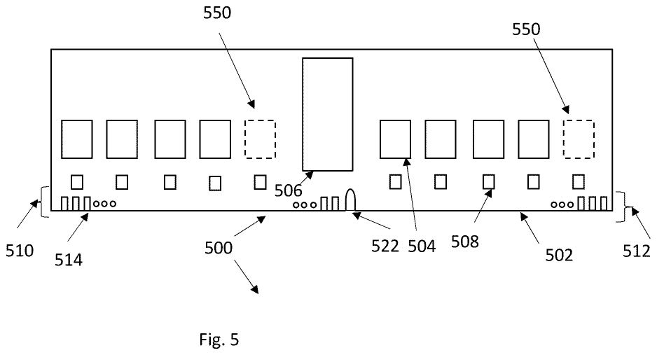

Referring now to FIG. 5, DDR5 64 bit DIMM 312 is shown in more detail. A printed circuit board 502 is shaped to support ten (10)×8 DRAM chips on one side thereof of which only eight (8)×8 DRAM chips 504 are present and two DRAM chip spaces 550 are left unpopulated. Also present are a central registered clock driver (RCD chip) 506, data buffers 508, and left and right pin sets 510 and 512 of individual pins 514 extending along the bottom of printed circuit board 402. A key slot 522 is sized and positioned to mate with a projection of 80bit socket 314 of the supporting architecture (e.g., server, computer) to connect to the supporting architecture. Other components per the DDR5 standard as are known in the art (e.g., PMIC, SPD hub, temperature sensor, wiring, connectors, etc.) are not shown. The 64 bit DIMM 316 may thus be made in part from standard off the shelf components as used in DIMMs, but with space for 16 bits of DRAM chips being left unpopulated.

The 64 bit DIMM 312 thus has the size and shape of an 80 bit DIMM and can interface with an 80 bit socket, but due to the unpopulated slots has 64 bits of processing capacity. In combination with the 80 bit DIMM 308, a total processing capability of 144 bits is provided for the channel.

The above configuration provides several improvements over the 160 bit DIMM configuration of the prior art.

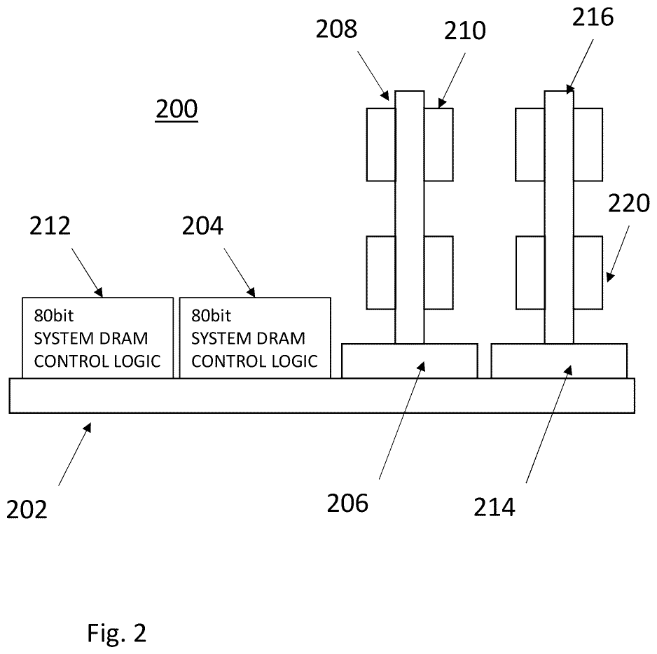

A first improvement is in the number of pins in pin set 318 of 144 bit controller 304 compared to the prior art two 80 bit controllers of FIG. 2, and corresponding savings in space and power.

One savings is in the number of data pins. The prior art needed 160 data pins whereas the above embodiment needs only 144, with a corresponding savings of 16 pins.

Another savings is in the number of clocking pins. The prior art needed 80 clocking pins (40 for each controller), whereas the above embodiment only requires 36 pins, with a corresponding savings of 44 pins.

Another savings is in the number of command/address pins. The prior art needed 40 clocking pins (20 for each controller), whereas the above embodiment only requires 20 pins due to the presence of a single controller for a corresponding savings of 20 pins.

Another savings is the number of shield pins. One (1) shield pin is used per each data pin, per two clocking pins, and per address/command pin. Overall, the embodiment above thus utilizes about 58 fewer shield pins compared to the prior art.

Another savings is in the number of power pins. One (1) power pin is used per each pin other than a shield pin. Overall, the embodiment above thus utilizes about 80 fewer power pins compared to the prior art.

Collectively, the embodiment above utilizes between 200-250 less pins than the prior art. That savings is per channel, such that for sixteen (16) channels some 3000-4000 less pins are used.

The reduction in pins allow for printed circuit board 302 to have less layers than the prior art printed circuit board 202, thus reducing costs of manufacture.

The above embodiment also operates at lower power than the prior art. Since there are only 144 bits of DRAM chips compared to 160 bits of DRAM chips, some 10% power savings is achieved alone due to the smaller number of DRAM chips. Power usage is also proportional to the number of data, command/address and clocking pins used for transmission, providing on the order of another 10% savings in power consumption.

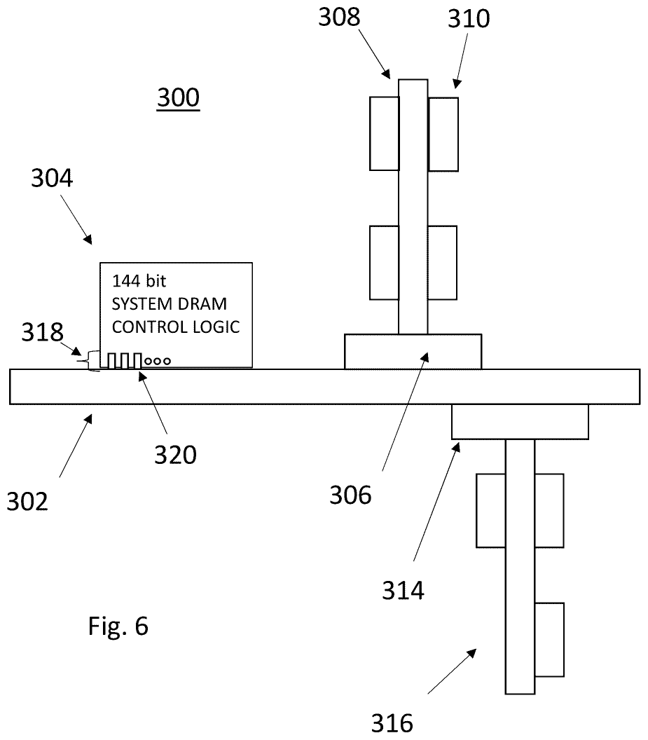

In the above embodiments, the DIMMs are shown on top of the circuit board. However, the invention is not so limited, and one or both of the DIMMs could be on the bottom of the circuit board. Referring now to FIG. 6, an architecture 600 is shown in which the 64 bit DIMM 316 and 80 bit socket 314 are mounted on the bottom side of the printed circuit board 302. Since 80 bit DIMM 308 has more processing capacity than 64 bit DIMM 316 it will run hotter, and thus 64 bit DIMM 316 may be the cooler option to mount below the printed circuit board 302. However, the invention is not so limited, and the 64 bit DIMM 316 could be mounted on the top of the printed circuit board 302 while the 80 bit DIMM 308 is mounted on the bottom of the printed circuit board 302.

In an alternative embodiment, the two DIMMS could each have 72 bits of DRAM chips, thus providing a collective 144 bits of processing capacity. In this case, each of the DIMMS would be sized and shaped for 80 bits, but some of the spacing for DRAM chips would be left unpopulated to reduce the overall processing capacity to 72 bits per DIMM.

The above embodiment refers to use of ×8 DDR chips. However, the invention is not so limited, and other sizes (e.g., ×4, ×12, ×16, or combinations thereof).

The specification and drawings are to be regarded in an illustrative rather than a restrictive sense. It will, however, be evident that various modifications and changes may be made thereunto without departing from the broader spirit and scope of the invention as set forth in the claims.

What is claimed is:

1. A dual in-line memory module (DIMM) system, comprising
a printed circuit board;
a 144 bit system controller mounted on the printed circuit board;
first and second 80 bit sockets mounted on the printed circuit board and connected to the 144 bit system controller;
a first DIMM connected to the first 80 bit socket;
a second DIMM connected to the second 80 bit socket; and
a total processing capacity of the first and second DIMMs combined being 144 bits;
wherein the 144 bit system controller communicates with the first and second 80 bit sockets and the first and second DIMMs by a 128 byte cache line.

2. The DIMM system of claim 1, wherein the first DIMM is an 80 bit DIMM populated with 80 bits of DRAM chips.

3. The DIMM system of claim 1, wherein the second DIMM is a 64 bit DIMM.

4. The DIMM system of claim 1, wherein the second DIMM is an 80 bit sized DIMM populated with 64 bits of DRAM chips.

5. The DIMM system of claim 1, wherein the second DIMM has 16 bits of DRAM chip space unpopulated.

6. The DIMM system of claim 1, wherein the first 80 bit socket is mounted on a top side of the printed circuit board, and the second 80 bit socket is mounted on a bottom side of the printed circuit board.

7. The DIMM system of claim 1, wherein the system controller has 36 clocking pins.

8. The DIMM system of claim 1, wherein the system controller has 144 data pins.

9. The DIMM system of claim 1, wherein the first DIMM is a 72 bit DIMM, and the second DIMM is a 72 bit DIMM.

10. A dual in-line memory module (DIMM) system, comprising
a printed circuit board;
a 144 bit system controller mounted on the printed circuit board;
first and second 80 bit sockets mounted on the printed circuit board and connected to the 144 bit system controller;
a first DIMM connected to the first 80 bit socket, the first DIMM being an 80 bit DIMM populated with 80 bits of DRAM chips;
a second DIMM connected to the second 80 bit socket, the second DIMM being an 80 bit sized DIMM populated with 64 bits of DRAM chips and has 16 bits of DRAM chip space unpopulated; and
a total processing capacity of the first and second DIMMs combined being 144 bits;
wherein the 144 bit system controller communicates with the first and second 80 bit sockets and the first and second DIMMs by a 128 byte cache line.

11. The DIMM system of claim 10, wherein the first 80 bit socket is mounted on a top side of the printed circuit board, and the second 80 bit socket is mounted on a bottom side of the printed circuit board.

12. The DIMM system of claim 10, wherein the system controller has 36 clocking pins.

13. The DIMM system of claim 10, wherein the system controller has 144 data pins.
